(19) United States
(12) Patent Application Publication
(10) Pub. No.: US 2005/0201133 A1
(43) Pub. Date: Sep. 15, 2005

(54) Storage device unit including cooling device

(75) Inventors: Koichiro Oba, Kawasaki (JP); Naotoshi Katahara, Kawasaki (JP); Susumu Yamashita, Kawasaki (JP); Takayuki Bitoh, Kawasaki (JP)

Correspondence Address: Patrick G. Burns, Esq.;GREER, BURNS & CRAIN, LTD., Suite 2500, 300 South Wacker Drive, Chicago, IL, 60606, US

(73) Assignee: Fujitsu Limited

(21) Appl. No.: 11/055,002

(22) Filed: Feb. 10, 2005

Related U.S. Application Data
(62) Division of application No. 10/796,660, filed on Mar. 8, 2004, now abandoned.
Application No. 10/796,660 is a continuation of application No. PCT/JP01/11584, filed on Dec. 27, 2001.

(51) Int. Cl. G11C 5/00

(52) U.S. Cl. 365/52

(57) ABSTRACT

A storage device unit includes a storage device containing a recording medium in a housing. A heat radiation device is attached to the storage device outside the housing. The storage device unit enables prevention of rise in the temperature of the storage device based on the action of the heat radiation device. The storage device keeps normally operating in a high temperature condition. Moreover, the heat radiation device can be attached to a conventional storage device, so that it is possible to avoid the redesign of the storage device. The storage device having a resistance to high temperature can be provided in this manner at a lower cost.

### BACKGROUND OF THE INVENTION

1. Field of the Invention

The present invention relates to a storage device including a magnetic storage device such as a hard disk drive (HDD), for example.

2. Description of the Prior Art

A hard disk drive is in general employed in a computer. The computer mostly works in the usual environment. The hard disk drive is usually separated from a hard or tough condition such as high temperature, high humidity, and the like. The hard disk drive is thus not so far required to have resistance to high temperature, high humidity, and the like.

Many proposals are recently made for utilization of the hard disk drive in various products. It is expected that the hard disk drive is used in a severer environment. The hard disk drive may be required to normally operate in a higher temperature condition. One option is that the hard disk drive is totally redesigned to meet the requirement. However, such a redesign will require much labor and cost.

### SUMMARY OF THE INVENTION

It is accordingly an object of the present invention to provide a storage device such as a hard disk drive capable of reliably keeping operating in a higher temperature condition, possibly without a redesign of the hard disk drive.

According to a first aspect of the present invention, there is provided a storage device unit comprising: a storage device containing a recording medium in a housing; and a heat radiation device attached to the storage device outside the housing.

The storage device unit enables prevention of rise in the temperature of the storage device based on the action of the heat radiation device. The storage device keeps normally operating in a high temperature condition. Moreover, the heat radiation device can be attached to a conventional storage device, so that it is possible to avoid the redesign of the storage device. The storage device having a resistance to high temperature can be provided in this manner at a lower cost.

The heat radiation device may include: a base member having a thermal conductivity and contacting the storage device; and a fin member having a thermal conductivity and contacting the base member. The heat radiation device of this type serves to efficiently transfer heat of the storage device to the base member. The heat of the base member is thereafter efficiently radiated from the fin member. The storage device is thus prevented from rise in the temperature.

Alternatively, the heat radiation device may include: a base member having a thermal conductivity and contacting the storage device; and a fin extending from a back surface of the base member. The heat radiation device of this type serves to efficiently transfer heat of the storage device to the base member. The heat of the base member is thereafter efficiently radiated from the fin. The storage device is thus prevented from rise in the temperature.

Otherwise, the heat radiation device may include: a base member having a thermal conductivity and contacting the storage device; a heat pipe contacting the base member; and a fin having a thermal conductivity and connected to the heat pipe. The heat radiation device of this type serves to efficiently transfer heat of the storage device to the base member. The heat of the base member is thereafter efficiently transferred to the fin based on the action of the heat pipe. The heat is efficiently radiated from the fin. The storage device is thus prevented from rise in the temperature.

Any of the heat radiation devices may further include a guide surface defined on the base member or the fin member. The guide surface is allowed to contact a predetermined guide fixed within an enclosure, enclosing the storage device, the base member and the fin, when the guide surface guides movement of the storage device with respect to the enclosure. The guide surface enables a smooth attachment and removal of the storage device unit or the storage device to and from the enclosure. The heat radiation device can also independently be attached to and removed from the enclosure.

A thermally-conductive sheet made of a non-silicon material is preferably interposed between the storage device and the base member in the storage device units. The thermally-conductive sheet improve the contact between the storage device and the base member. Heat of the storage device is efficiently transferred to the base member. The storage device is efficiently prevented from rise in the temperature. In particular, exclusion of silicon-based materials from the thermally-conductive sheet reliably prevents generation of a silicon gas within the storage device units. In the case where a magnetic storage device such as a hard disk drive is employed as the storage device, the magnetic recording medium can reliably be prevented from corrosion due to a silicon gas.

According to a second aspect of the present invention, there is provided a cooling device comprising: an enclosure defining a space containing an electronic component; a thermally-conductive base member contained in the enclosure and defining a surface for receiving the electronic component; a fin member having a thermal conductivity and contacting the base member; a guide stationarily located in the enclosure; and a guide surface defined on at least one of the base member and the fin member, the guide surface being received on the guide to guide movement of the base member with respect to the space of the enclosure.

In addition, according to a third aspect of the present invention, there is provided a cooling device comprising: an enclosure defining a space containing an electronic component; a thermally-conductive base member contained in the enclosure and defining a surface for receiving the electronic component; a fin extending from a back surface of the base member; a guide stationarily located in the enclosure; and a guide surface defined on the base member, the guide surface being received on the guide to guide movement of the base member with respect to the space of the enclosure.

Still, according to a fourth aspect of the present invention, there is provided a cooling device comprising: an enclosure defining a space containing an electronic component; a thermally-conductive base member contained in the enclosure and defining a surface for receiving the electronic component; a heat pipe contacting the base member; a fin having a thermal conductivity and connected to the heat pipe; a guide stationarily located in the enclosure; and a guide surface defined on the base member, the guide surface being received on the guide to guide movement of the base member with respect to the space of the enclosure.

Any of the cooling devices allows attachment and detachment of the base member or the fin member to and from the enclosure. The base member and the fin member can be positioned at a predetermined position within the enclosure. The fin member or the fin can thus reliably be located within airflow. In this case, the cooling device may further include a stop restraining the movement of the base member in the enclosure when the base member or the fin member is inserted into the enclosure.

The cooling device may further include a fan positioned relative to the base member within the enclosure. The fan serves to generate airflow within the enclosure. The fin member or the fin can be located within the airflow in the aforementioned manner. The enclosure may also be utilized as an enclosure for an electronic apparatus utilizing the electronic component.

The electronic component may include, in addition to the aforementioned storage device, any type that generates heat when operating. The aforementioned storage device unit may be employed in a car navigation system, a digital audio device, an audiovisual device, a digital television device, a game machine, and other types of electronic apparatus.

### BRIEF DESCRIPTION OF THE DRAWINGS

The above and other objects, features and advantages of the present invention will become apparent from the following description of the preferred embodiments in conjunction with the accompanying drawings, wherein:

FIG. 1 illustrates a passenger room of an automobile;

FIG. 2 is a perspective view illustrating the externals of a car navigation system;

FIG. 3 is an exploded view schematically illustrating the structure of the car navigation system;

FIG. 4 is an exploded view schematically illustrating the structure of a hard disk drive (HDD) unit according to a first embodiment of the present invention;

FIG. 5 is an exploded view schematically illustrating the structure of a heat radiation device;

FIG. 6 is a partial sectional view of the car navigation system for schematically illustrating the flow of air in the car navigation system;

FIG. 7 is an exploded view schematically illustrating the structure of a HDD unit according to a second embodiment of the present invention;

FIG. 8 is an exploded view schematically illustrating the structure of a HDD unit according to a third embodiment of the present invention;

FIG. 9 is a perspective view schematically illustrating the structure of a heat radiation device; and

FIG. 10 is an exploded view schematically illustrating the structure of a HDD unit according to a modification of the third embodiment.

### DESCRIPTION OF THE PREFERRED EMBODIMENTS

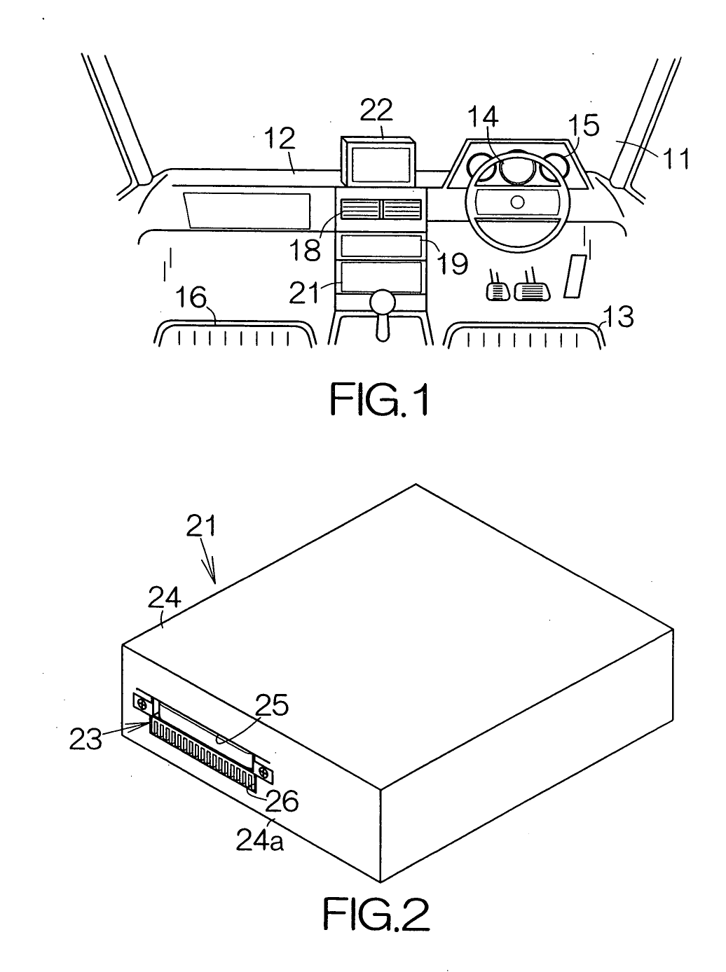

FIG. 1 schematically illustrates a passenger room of an automobile. A dashboard 12 is disposed to extend in the lateral direction of the body of the automobile along a windshield 11. The dashboard 12 serves to partition the passenger room from an engine room, not shown. Gauges and instruments such as a speedometer 14, a tachometer 15, and the like, are embedded in the dashboard 12 near the driver's seat 13. A ventilator 18, an audio device 19, a car navigation system 21, and the like are embedded in the dashboard 12 between the driver's seat and a passenger seat 16. The car navigation system 21 is connected to a display device 22 attached on the dashboard 12. The car navigation system 21 is designed to calculate the current position of the automobile, a route to a destination, and the like, based on map information. The display device 22 displays map and other information on the screen based on video signals supplied from the car navigation system 21.

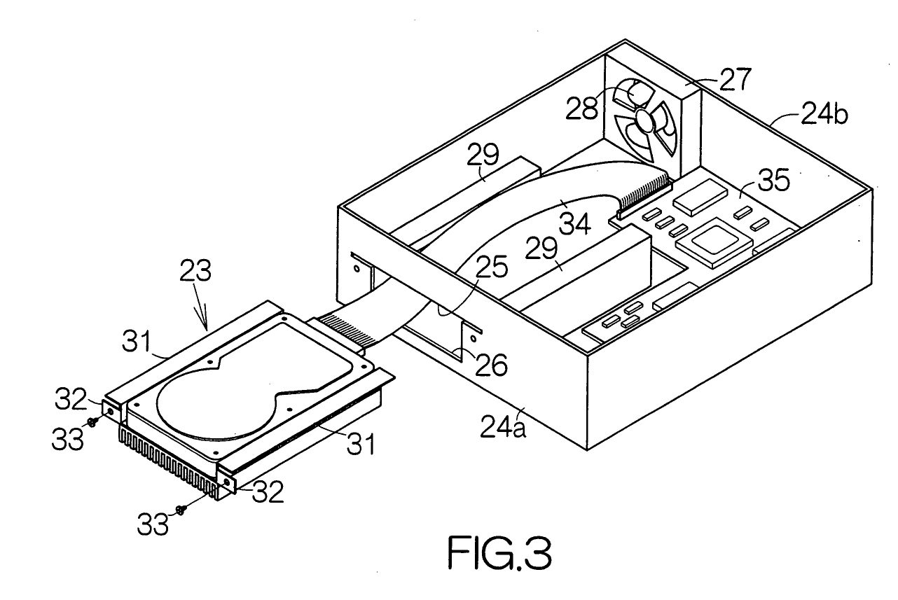

As shown in FIG. 2, the car navigation system 21 includes an enclosure 24 defining an inside space containing a mass storage device unit or hard disk drive (HDD) unit 23, for example. Additionally, a global positioning system (GPS) sensor and a central processing unit (CPU) are enclosed within the inside space of the enclosure 24. The GPS sensor is designed to detect the position based on the GPS. The CPU is capable of calculating the position on the map and a route to a destination based on the positional information from the GPS sensor and the map information obtained from a HDD in the HDD unit 23.

An opening 25 is defined in a front panel 24a of the enclosure 24. The opening 25 is designed to connect the outside and inside spaces of the enclosure 24 to each other. The HDD unit 23 can be inserted into the space within the enclosure 24 from the opening 25. After the HDD unit 23 has been inserted into the enclosure 24, a ventilation window 26 is still defined in the opening 25. The ventilation window 26 is designed to connect the outside and inside spaces of the enclosure 24 to each other. The front panel 24a of the enclosure 24 may be covered with a separate dressed panel, not shown, unless the dressed panel blocks the ventilation window 26.

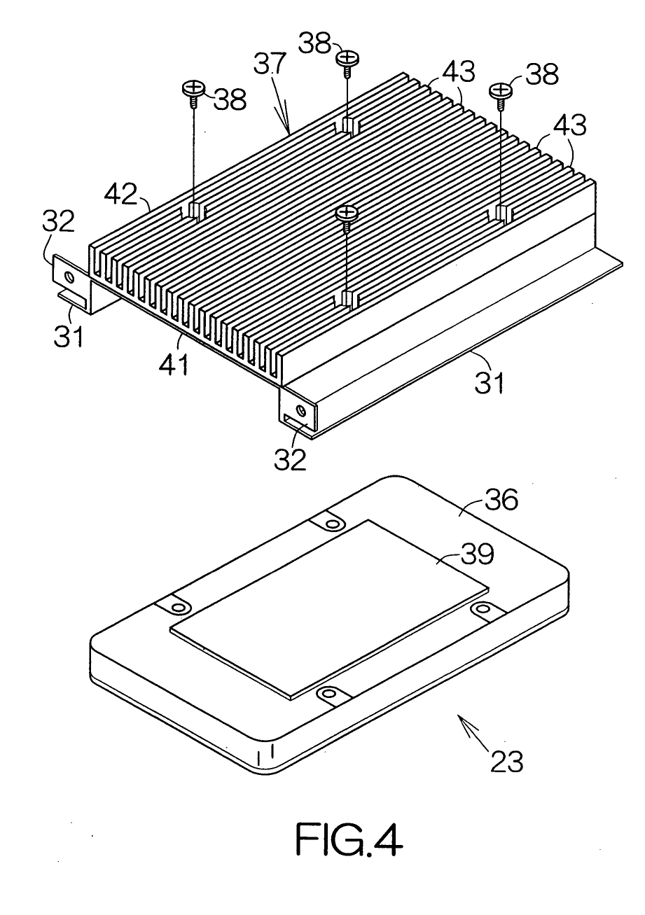

As shown in FIG. 3, a fan unit 27 is located in a back panel 24b of the enclosure 24. The fan unit 27 is designed to have an axial flow fan 28 rotating around a rotation axis perpendicular to the back panel 24b. The axial flow fan 28 serves to suck the air out of the inside space of the enclosure 24. Airflow is induced within the inside space of the enclosure 24 from the opening 25 or the ventilation window 26 to the axial flow fan 28. In other words, an airflow passage can be established from the ventilation window 26 to the axial flow fan 28.

A pair of guide or guide rail 29, 29 are disposed within the enclosure 24. The guide rails 29 are designed to extend from the opening 25 toward the back panel 24b, namely, toward the axial flow fan 28. The guide rails 29 are arranged in parallel with each other on a predetermined horizontal plane. The guide rails 29 are fixed to the enclosure 24 within the inside space, for example. The enclosure 24 thus reliably fixes the positional relationship between the guide rails 29 and the axial flow fan 28.

Guide plates 31, 31 are located in the HDD unit 23 at the sides. The guide plates 31, 31 are designed to extend in parallel with each other on a predetermined horizontal plane. The guide plates 31 define guide surfaces of the present invention. When the HDD unit 23 is inserted into the inside space of the enclosure 24 from the opening 25, the guide plates 31 of the HDD unit 23 are received on the upper surfaces of the corresponding guide rails 29, respectively, at the guide surfaces. The guide plates 31 are allowed to slide on the corresponding guide rails 29. The movement of the HDD unit 23 is in this manner guided with respect to the enclosure 24. It should be noted that a guide mechanism may have any structure other than the combination of the guide rails 29 and the guide plates 31.

A pair of stop plate 32, 32 are located in the HDD unit 23 at the front end. The stop plates 32, 32 are designed to extend along a vertical plane perpendicular to the aforementioned horizontal plane. The stop plates 32 serve as stops of the present invention. When the HDD unit 23 is inserted in the inside space of the enclosure 24 from the opening 25, the stop plates 32, 32 of the HDD unit 23 are received on the front panel 24a of the enclosure 24. The movement of the HDD unit 23 into the enclosure 24 is restrained in this manner. This restraint serves to position the HDD unit 23 at a predetermined position within the inside space of the enclosure 24. A fixed positional relationship can thus be established between the HDD unit 23 and the axial flow fan 28. Screws 33 may be employed to fix the stop plates 32 on the front panel 24a of the enclosure 24, for example.

A flexible connecting cable 34 has an end connected to the rear end of the HDD unit 23. The other end of the flexible connecting cable 34 is connected to a printed circuit board 35 located within the enclosure 24. Transmission paths can in this manner be established for data and electric power between the HDD unit 23 and the printed circuit board 35. The aforementioned GPS sensor and CPU are mounted on the printed circuit board 35.

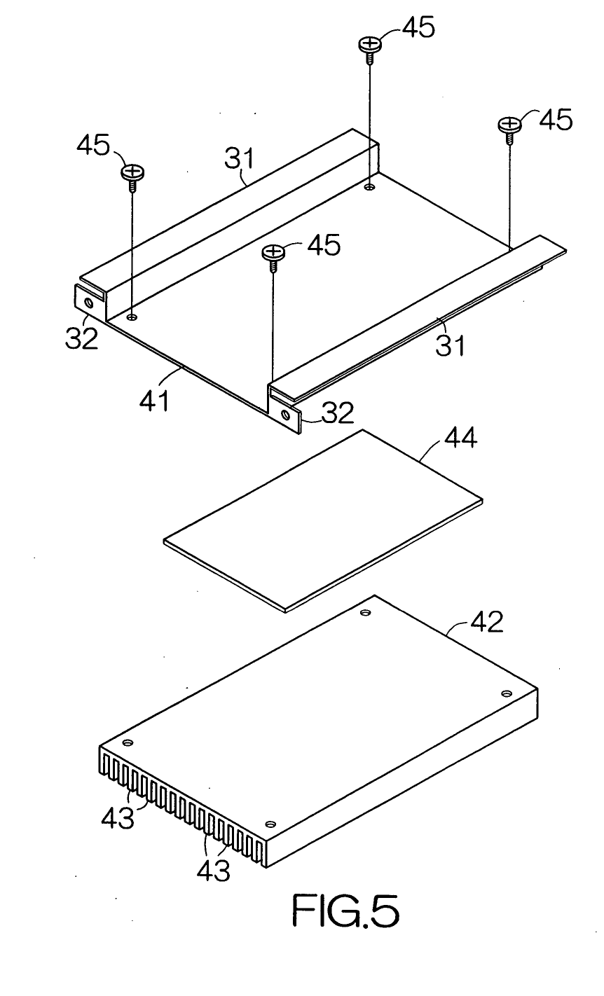

FIG. 4 illustrates the HDD unit 23 according to a first embodiment of the present invention. The HDD unit 23 includes a HDD 36 containing a recording medium or media in a housing, and a heat radiation device 37 attached to the HDD 36 outside the housing. The recording medium or medium correspond to a hard disk or disks, or a magnetic recording disk or disks. The heat radiation device 37 is superposed over the back surface of the HDD 36. A printed circuit board is located at the back surface of the HDD 36. A semiconductor chip such as a hard disk controller, a connector receiving the other end of the flexible connecting cable 34, and the like, are mounted on the printed circuit board in a conventional manner. A coupling device such as screws 38 may be employed to fix the heat radiation device 37 to the HDD 36, for example. The housing of the HDD 36 encloses, in addition to the aforementioned hard disk or disks, a spindle motor driving the hard disk or disks for rotation, a head used to write and read magnetic information data into and out of the hard disk or disks, an actuator arm supporting the head, a voice coil motor driving the actuator arm for swinging movement, and other related components.

A thermally-conductive sheet 39 is interposed between the HDD 36 and the heat radiation device 37. The thermally-conductive sheet 39 has a predetermined elasticity. The thermally-conductive sheet 39 may be made of a non-silicon material, for example. A siloxaneless sheet can be employed as the thermally-conductive sheet 39. The heat radiation device 37 uniformly fays with the back surface of the HDD 36 based on the elasticity of the thermally-conductive sheet 39. A close contact can be achieved between the heat radiation device 37 and the HDD 36, so that heat generated at the HDD 36 is efficiently transferred to the heat radiation device 37. The thermally-conductive sheet 39 may have a thermal conductivity at least larger than that of air.

Referring also to FIG. 5, the heat radiation device 37 includes a base member or plate 41 defining a flat front surface receiving the HDD 36. The base plate 41 has a thermal conductivity at least larger than that of air. A heat sink member or heat radiation fin member 42 is superposed on the back surface of the base plate 41. The front surface of the base plate 41 fays with the back surface of the HDD 36 based on the elasticity of the thermally-conductive sheet 39 as described above. The base plate 41 may be shaped out of a plate material having a higher thermal conductivity, such as an aluminum plate, for example, based on press machining. The guide plates 31 and the stop plates 32 can simultaneously be punched out of the material for the base plate 41. In other words, the base plate 41, the guide plates 31 and the stop plates 32 can be shaped out of a single plate material. The base plate 41 can independently be inserted into and removed from the enclosure 24 based on the cooperation of the guide rails 29 and the guide plates 31. The enclosure 24 and the heat radiation device 37 in combination establish a cooling device of the present invention.

Fins 43 are formed on the heat radiation fin member 42. The individual fins 43 are designed to extend from the front end to the rear end of the HDD 36. The fins 43 are positioned at predetermined positions within the enclosure 24 based on the cooperation of the guide plates 31 and the stop plates 32 integral to the base plate 41. An airflow passage is defined between the adjacent fins 43 so as to guide air flowing from the ventilation window 26 to the axial flow fan 28 when the HDD unit 23 is enclosed within the enclosure 24. The heat radiation fin member 42 may be formed from material having a higher thermal conductivity, such as aluminum, based on extrusion.

As is apparent from FIG. 5, a thermally-conductive sheet 44 is interposed between the back surface of the base plate 41 and the heat radiation fin member 42. The thermally-conductive sheet 44 has a predetermined elasticity. The thermally-conductive sheet 44 may be made of a non-silicon material, for example. A siloxaneless sheet can be employed as the thermally-conductive sheet 44. The heat radiation fin member 42 uniformly fays with the back surface of the base plate 41 based on the elasticity of the thermally-conductive sheet 44. A close contact can thus be achieved between the heat radiation fin member 42 and the base plate 41, so that heat of the base plate 41 is efficiently radiated from the heat radiation fin member 42. Screws 45 may be employed to couple the heat radiation fin member 42 with the base plate 41, for example. It should be noted that any coupling device can be employed in place of the screws 45. The thermally-conductive sheet 44 may have a thermal conductivity at least larger than that of air.

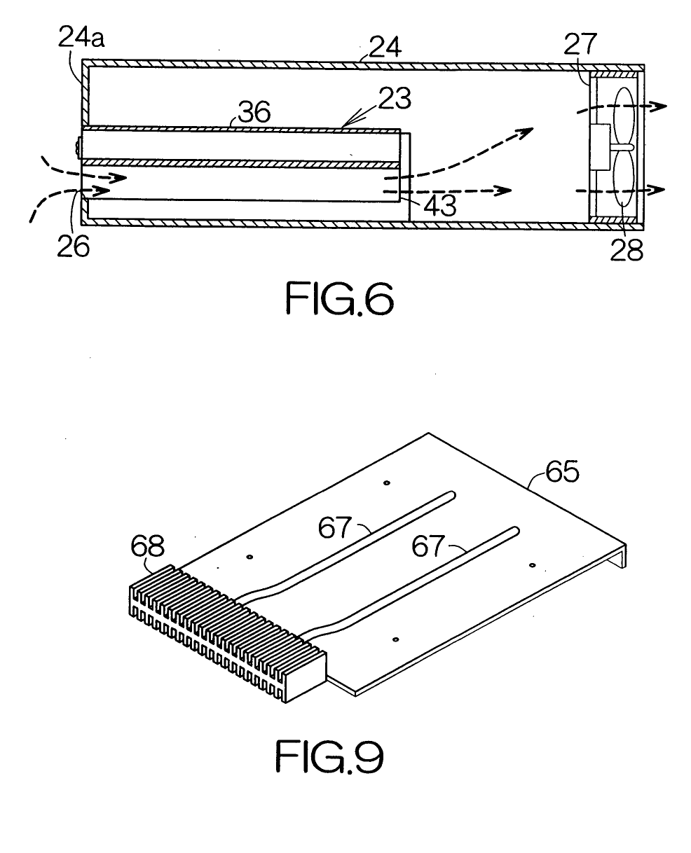

Assume that the automobile is left in the sun in a hot summer day, for example. The temperature reaches over 100 degree Celsius around the dashboard 12. As shown in FIG. 6, when the axial flow fan 28 operates, air is forced to flow from the opening 25 or the ventilation window 26 to the axial flow fan 28. The air is allowed to absorb heat from the individual fins 43. The airflow promotes heat radiation from the fins 43. The HDD 36 can be prevented from rise in the temperature. The HDD 36 keeps normally operating in the high temperature condition.

The aforementioned heat radiation device 37 can be attached to a conventional HDD 36, so that the redesign of the HDD 36 can be avoided. The HDD 36 having a sufficient resistance to a higher temperature can be provided at a lower cost. Moreover, the aforementioned heat radiation device 37 serves to position the fins 43 of the heat radiation device 37 relative to the axial flow fan 28 every time when the heat radiation device 37 or the HDD unit 23 is inserted into the enclosure 24. The fins 43 are reliably positioned within airflow. The heat radiation from the fins 43 can reliably be promoted.

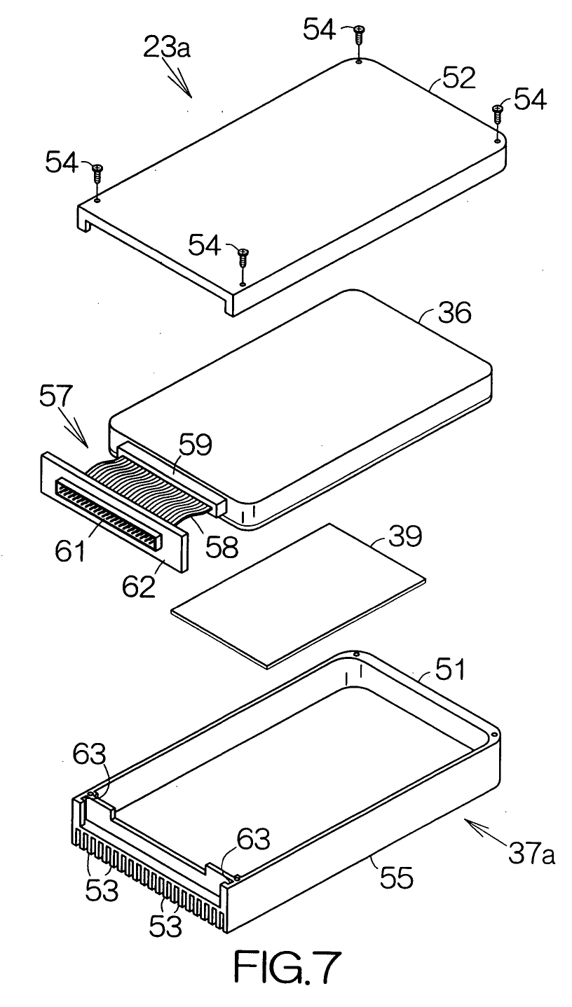

FIG. 7 illustrates the HDD unit 23a according a second embodiment of the present invention. The heat radiation device 37a of the second embodiment includes a heat sink member or base member 51 defining a flat front surface receiving the HDD 36. The base member 51 has a thermal conductivity at least larger than that of air. A cover 52 is coupled with the base member 51. The cover 52 serves to define an inner space between the base member 51 and the cover 52 itself. The HDD 36 is located within the inner space. The cover 52 is made of a resin material. Heat radiation fins 53 are continuously and integrally formed on the back surface of the base member 51. The base member 51 may be made of material having a higher thermal conductivity, such as aluminum, based on casting process. Screws 54 may be employed to couple the cover 52 with the base member 51, for example. When the cover 52 is coupled with the base member 51, the HDD 36 in the inner space is urged against the surface of the base member 51. The base member 51 is allowed to uniformly fay with the back surface of the HDD 36 based on the elasticity of the thermally-conductive sheet 39 in the same manner as descried above. A close contact can thus be established between the HDD 36 and the base member 51, so that the heat generated at the HDD 36 is efficiently transferred to the base member 51. Like reference numerals are attached to the structure or components equivalent to those of the aforementioned first embodiment.

The heat radiation fins 53 extend from the front end to the rear end of the HDD 36. In this case, a guide surface 55 is defined on the outer surface of the base member 51. The guide surface 55 may extend over the side surfaces and the bottom surface of the base member 51. The guide surface 55 serves to position the heat radiation fins 53 at predetermined positions within the enclosure 24. The guide rails 29 or the like may serve to guide the guide surface 55 in the same manner as described above. An airflow passage is defined between the adjacent fins 53 so as to guide air flowing from the ventilation window 26 to the axial flow fan 28.

An intermediate connecting unit 57 is coupled to an exterior connector, not shown, of the HDD 36. The intermediate connecting unit 57 includes a flexible printed wiring board 58, for example. The flexible printed wiring board 58 is held between the base member 51 and the cover 52 when the cover 52 is coupled with the base member 51. A first connector 59 is attached to one end of the flexible printed wiring board 58. The first connector 59 is coupled with the exterior connector of the HDD 36. The first connector 59 is located inside the inner space defined between the base member 51 and the cover 52. On the other hand, a second connector 61 is attached to the other end of the flexible printed wiring board 58. The second connector 61 is located outside the cover 52 and the base member 51. Individual terminals or pins of the first connector 59 are connected to the corresponding terminals or pins of the second connector 61 through wiring patterns extending over the flexible printed wiring board 58. Transmission paths can thus be established for data and electric power between the HDD 36 and the second connector 61.

The second connector 61 is supported on an attachment plate 62 at the other end of the flexible printed wiring board 58 in the intermediate connecting unit 57. The lateral ends of the attachment plate 62 are received in guide grooves 63 defined in the base member 51, for example. The second connector 61 is reliably prevented from dropping from the base member 51 in the HDD unit 23a when the cover 52 is coupled with the base member 51. The guide grooves 63 serve to prevent a relative movement between the base member 51 and the attachment plate 62.

When the HDD unit 23a is incorporated within the enclosure 24 in the same manner as described above, heat radiation from the heat radiation fins 53 is promoted. The HDD 36 can be prevented from rise in the temperature. The HDD 36 keeps normally operating in the high temperature condition. The heat radiation device 37a can be attached to a conventional HDD 36, so that the redesign of the HDD 36 can be avoided. Moreover, the heat radiation device 37a serves to position the heat radiation fins 53 relative to the axial flow fan 28 every time when the heat radiation device 37a or the HDD unit 23a is inserted into the enclosure 24. The heat radiation fins 53 are reliably positioned within airflow.

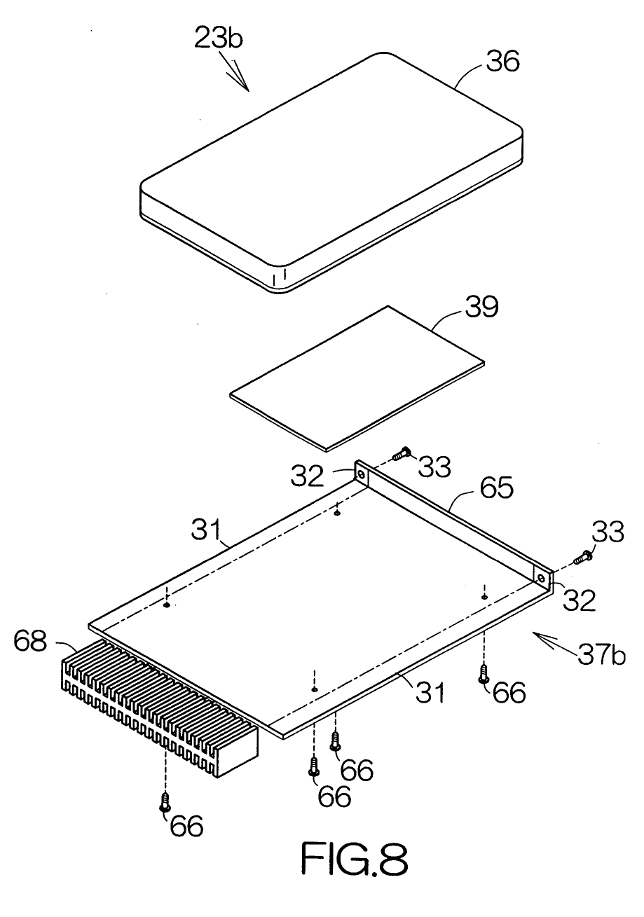

FIG. 8 illustrates the HDD unit 23b according to a third embodiment of the present invention. The heat radiation device 37b of the third embodiment includes a base member or plate 65 defining a flat front surface receiving the HDD 36. The base plate 65 may be similar to the aforementioned base plate 41. The guide plates 31 and the stop plates 32 are continuously and integrally formed on the base plate 65 in the same manner as described above. A coupling device such as screws 66 is employed to fix the base plate 65 to the HDD 36, for example. The front surface of the base plate 65 is allowed to fay with the back surface of the HDD 36 based on the elasticity of the thermally-conductive sheet 39 in the same manner as described above. A close contact can thus be established between the base plate 65 and the HDD 36, so that heat generated at the HDD 36 is efficiently transferred to the base plate 65. Like reference numerals are attached to the structure or components equivalent to those of the aforementioned first and second embodiments.

Referring also to FIG. 9, heat pipes 67 are fixed to the back surface of the base plate 65. A close contact is established between the heat pipes 67 and the back surface of the base plate 65. Heat radiation fins 68 are coupled to the ends of the heat pipes 67. The heat pipes 67 serve to efficiently transfer heat from the base plate 65 to the heat radiation fins 68. The heat pipes 67 are a tube containing an appropriate amount of working fluid in a vacuum condition in a conventional manner.

When the HDD unit 23b is incorporated within the enclosure 24 in the same manner as described above, heat radiation from the heat radiation fins 68 is promoted. The HDD 36 can be prevented from rise in the temperature. The HDD 36 keeps normally operating in the high temperature condition. The heat radiation device 37b can be attached to a conventional HDD 36, so that the redesign of the HDD 36 can be avoided. Moreover, the heat radiation device 37b serves to position the heat radiation fins 68 relative to the axial flow fan 28 every time when the heat radiation device 37b or the HDD unit 23b is inserted into the enclosure 24. The heat radiation fins 68 are reliably positioned within airflow.

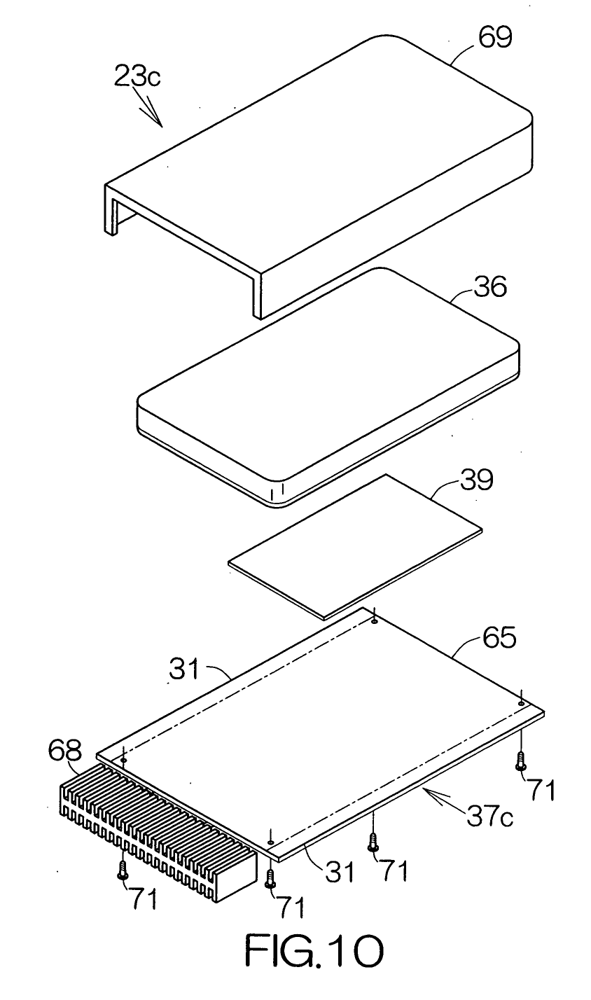

FIG. 10 illustrates the HDD unit 23c according to a modification of the third embodiment. The heat radiation device 37c of the modification further includes a cover 69 coupled with the base plate 65. The cover 69 serves to define an inner space between the base plate 65 and the cover 69 itself. The HDD 36 is located within the inner space. The cover 69 is made of a resin material. Screws 71 may be employed to couple the cover 69 with the base plate 65, for example. When the cover 69 is coupled with the base plate 65, the HDD 36 in the inner space is urged against the surface of the base plate 65. The front surface of the base plate 65 is allowed to fay with the back surface of the HDD 36 based on the elasticity of the thermally-conductive sheet 39 in the same manner as described above. A close contact can thus be established between the base plate 65 and the HDD 36, so that heat generated at the HDD 36 is efficiently transferred to the base plate 65. Like reference numerals are attached to the structure or components equivalent to those of the aforementioned third embodiment.

The aforementioned HDD unit may be employed in, in addition to the aforementioned car navigation system, a digital audio device, an audiovisual device, a digital television device, a game machine, and other types of electronic apparatus.

1-5. (canceled)

6. A storage device unit comprising:
a storage device containing a recording medium in a housing; and
a heat radiation device attached to the storage device outside the housing,
wherein the heat radiation device includes:
a base member having a thermal conductivity and contacting the storage device;
a heat pipe contacting the base member; and
a fin having a thermal conductivity and connected to the heat pipe.

7. The storage device unit according to claim 6, wherein a guide surface is defined on the base member, the guide surface contacting a predetermined guide fixed within an enclosure, enclosing the storage device, the base member and the fin, when the guide surface guides movement of the storage device with respect to the enclosure.

8-16. (canceled)

17. A cooling device comprising:
an enclosure defining a space containing an electronic component;
a thermally-conductive base member contained in the enclosure and defining a surface for receiving the electronic component;
a heat pipe contacting the base member;
a fin having a thermal conductivity and connected to the heat pipe;
a guide stationarily located in the enclosure; and
a guide surface defined on the base member, the guide surface being received on the guide to guide movement of the base member with respect to the space of the enclosure.

18. The cooling device according to claim 17, further comprising a stop restraining the movement of the base member in the enclosure.

19. The cooling device according to claim 17, further comprising a fan positioned relative to the base member within the enclosure.

20. (canceled)
